(19) United States
(12) Patent Application Publication
(10) Pub. No.: US 2026/0082758 A1
(43) Pub. Date: Mar. 19, 2026

(54) PHOTOVOLTAIC CELL, PHOTOVOLTAIC CELL MODULE AND PHOTOVOLTAIC CELL ASSEMBLY

(71) Applicant: Kunshan New Flat Panel Display Technology Center Co., Ltd., Kunshan (CN)

(72) Inventors: Shengzhi DONG, Kunshan (CN); Kui LV, Kunshan (CN); Xiaolin KANG, Kunshan (CN)

(73) Assignee: Kunshan New Flat Panel Display Technology Center Co., Ltd., Kunshan (CN)

(21) Appl. No.: 19/398,003

(22) Filed: Nov. 23, 2025

Related U.S. Application Data
(63) Continuation of application No. PCT/CN2023/137361, filed on Dec. 8, 2023.

(30) Foreign Application Priority Data
May 26, 2023 (CN) 202310605532.7
Oct. 30, 2023 (CN) 202311423054.4

(51) Int. Cl. H10K 30/88; H10K 30/50; H10K 85/50

(52) U.S. Cl. CPC H10K 30/88; H10K 30/50; H10K 85/50

(57) ABSTRACT

The present application relates to a photovoltaic cell, a photovoltaic cell module, and a photovoltaic cell assembly. The photovoltaic cell includes: a substrate; at least a cell body disposed on a surface of one side of the substrate; and an encapsulation structure disposed on a side of the cell body facing away from the substrate, an orthographic projection of the encapsulation structure covering an orthographic projection of the cell body in the thickness direction, and the encapsulation structure including a first inorganic layer, a first organic layer and a second inorganic layer which are stacked sequentially in a direction away from the cell body. The photovoltaic cell according to the embodiments of the present application can have an improved encapsulation effect and improved reliability.

### CROSS-REFERENCE TO RELATED APPLICATIONS

The present application is a continuation application of International Application No. PCT/CN2023/137361, filed on Dec. 8, 2023, which claims priority to Chinese Patent Application No. 202310605532.7, entitled “PHOTOVOLTAIC CELL AND PHOTOVOLTAIC CELL ASSEMBLY” and filed on May 26, 2023, and Chinese Patent Application No. 202311423054.4, entitled “PHOTOVOLTAIC CELL, PHOTOVOLTAIC CELL MODULE AND PHOTOVOLTAIC CELL ASSEMBLY” and filed on Oct. 30, 2023, both of which are incorporated herein by reference in their entirety.

### FIELD

The present application relates to the field of display, and in particular, to a photovoltaic cell, a photovoltaic cell module and a photovoltaic cell assembly.

### BACKGROUND

With the development of photovoltaic cell technology, at present, there are various photovoltaic cells made of different materials, such as crystalline silicon photovoltaic cells, conventional thin film photovoltaic cells, dye-sensitized photovoltaic cells, and perovskite photovoltaic cells. Taking perovskite photovoltaic cells as an example, part of photovoltaic cells are sensitive to moisture, oxygen, etc. in the air due to their material properties and thus require a good encapsulation effect. However, existing laminated encapsulation typically requires the use of an organic adhesive, which is prone to yellowing when exposed to solar radiation and easily reacts with glass substrates, etc., producing ions that corrode the photovoltaic cells, which results in a reduction in the overall reliability of the photovoltaic cells.

Therefore, there is an urgent need for a photovoltaic cell that has an improved encapsulation effect and improved reliability, and a corresponding photovoltaic cell module and photovoltaic cell assembly.

### SUMMARY

The present application provides a photovoltaic cell, a photovoltaic cell module and a photovoltaic cell assembly. The photovoltaic cell has an improved encapsulation effect and improved reliability.

In one embodiment, a photovoltaic cell is provided according to embodiments of the present application. The photovoltaic cell has a light-facing side and a back side which are disposed oppositely in a thickness direction of the photovoltaic cell, and includes: a substrate; a cell body disposed on a surface of a side of the substrate close to the light-facing side; and an encapsulation structure disposed on a side of the cell body facing away from the substrate, an orthographic projection of the encapsulation structure covering an orthographic projection of the cell body in a thickness direction, and the encapsulation structure including a first inorganic layer, a first organic layer and a second inorganic layer which are stacked sequentially in a direction away from the cell body.

In one embodiment, a photovoltaic cell module is provided according to embodiments of the present application. The photovoltaic cell module includes: a substrate; a cell body disposed on a surface of a side of the substrate close to the light-facing side; and an encapsulation structure disposed on a side of the cell body facing away from the substrate, an orthographic projection of the encapsulation structure covering an orthographic projection of the cell body in a thickness direction, and the encapsulation structure including a first inorganic layer, a first organic layer and a second inorganic layer which are stacked sequentially in a direction away from the cell body; and a bottom supplementary cell disposed on a side of the encapsulation structure facing away from the cell body and stacked with the encapsulation structure, where a light extraction module is provided between the cell body and the encapsulation structure.

In one embodiment, a photovoltaic cell assembly is provided according to embodiments of the present application. The photovoltaic cell assembly includes a photovoltaic cell according to any one of the embodiments or a photovoltaic cell module according to any one of the embodiments.

The photovoltaic cell according to the embodiments of the present application includes a substrate, a cell body and an encapsulation structure which are stacked sequentially. The encapsulation structure encapsulates the cell body by the inorganic layers and an organic layer which are stacked alternately, which can reliably achieve insulation from the external moisture and oxygen and also avoid the problems of radiation-induced yellowing, hydrolysis, etc. of an organic adhesive in an encapsulation structure that requires bonding, such as a glass lamination film, thereby effectively improving the encapsulation effect of photovoltaic cells to improve the reliability of cells.

### BRIEF DESCRIPTION OF THE DRAWINGS

Embodiments of the present application will be described below with reference to the accompanying drawings.

FIG. 1 is a structural schematic diagram of a photovoltaic cell according to an embodiment of the present application;

FIG. 2 is a cross-sectional view taken along line A-A′ in FIG. 1;

FIG. 3 is another cross-sectional view taken along line A-A′ in FIG. 1;

FIG. 4 is a cross-sectional view of a photovoltaic cell module according to an embodiment of the present application; and

FIG. 5 is a structural schematic diagram of a photovoltaic cell assembly according to an embodiment of the present application.

### DETAILED DESCRIPTION OF THE EMBODIMENTS

With the development of photovoltaic cell technology, photovoltaic cells in the market are gradually diversified. The perovskite photovoltaic cell technology has been rapidly developed thanks to their high light conversion efficiency. Since the highest photoelectric conversion efficiency of a single photovoltaic cell based on an organic-inorganic hybrid perovskite material has reached 25% or more, and a theoretical upper limit of the cell has exceeded an upper limit of a conventional crystalline silicon photovoltaic cell, there is a possibility of replacing the crystalline silicon cell with such cells.

On this basis, the applicant has found that the existing crystalline silicon photovoltaic cells are typically encapsulated using a glass lamination adhesive film encapsulation structure, and the perovskite photovoltaic cells are also encapsulated by the same encapsulation method. However, the material of the perovskite photovoltaic cells is more sensitive to moisture and oxygen in external environment, and easily degrades in the atmosphere. The organic adhesive used in the glass lamination adhesive film encapsulation is prone to hydrolysis in a hot and humid environment with light and oxygen, producing a material corrosive to the perovskite photovoltaic cell, and easily reacts with a glass substrate, etc., producing Na ions that cause a reduction in power of the photovoltaic cell. Moreover, the organic adhesive is also prone to yellowing when exposed to light radiation, affecting the overall light transmission of the cell.

In order to solve the above problems, the embodiments of the present application provide a photovoltaic cell, a photovoltaic cell module, and a photovoltaic cell assembly, in which a thin film encapsulation method with alternating organic and inorganic layers is used for encapsulation, leading to an effectively improved encapsulation effect and improved reliability of the photovoltaic cell.

The following embodiments of the present application are described only with a perovskite photovoltaic cell as an example. However, the present application is not limited thereto, and can also be applied to and protect photovoltaic cells made of other materials.

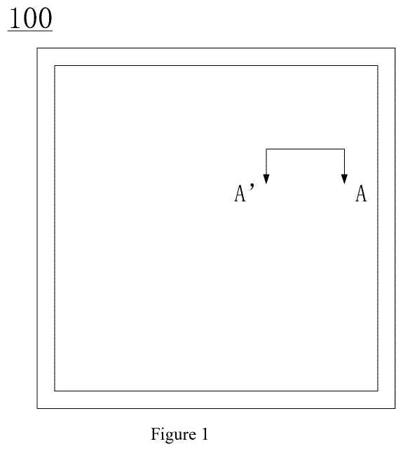

For better understanding of the present application, a photovoltaic cell, a photovoltaic cell module, and a photovoltaic cell assembly according to the embodiments of the present application are described in detail below with reference to FIGS. 1 to 5.

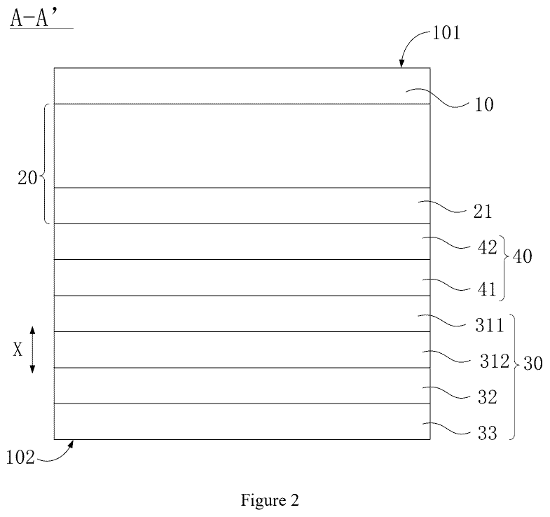

Referring to FIGS. 1 and 2 together, FIG. 1 is a structural schematic diagram of a photovoltaic cell according to an embodiment of the present application, and FIG. 2 is a cross-sectional view taken along line A-A′ in FIG. 1.

The embodiments of the present application provide a photovoltaic cell 100, including a light-facing side 101 and a back side 102 disposed oppositely in a thickness direction X of the photovoltaic cell. The photovoltaic cell 100 includes a substrate 10, a cell body 20, and an encapsulation structure 30, where the substrate 10 is disposed close to the light-facing side 101, and the cell body 20 is disposed on a surface of one side of the substrate 10; and the encapsulation structure 30 is disposed on a side of the cell body 20 facing away from the substrate 10, an orthographic projection of the encapsulation structure 30 covers an orthographic projection of the cell body 20 in the thickness direction X, and the encapsulation structure 30 includes a first inorganic layer 31, a first organic layer 32 and a second inorganic layer 33 which are stacked sequentially in a direction away from the cell body 20.

The embodiments of the present application provides a photovoltaic cell 100, including a substrate 10, a cell body 20 and an encapsulation structure 30 which are stacked sequentially in a direction from the light-facing side 101 to the back side 102. The substrate 10 is configured to support and fix the cell body 20. The cell body 20 is a body portion of the photovoltaic cell 100 for photoelectric conversion, and may specifically include a perovskite functional film layer and electrode layers on two sides of the functional film layer. The functional film layer may specifically include a film layer structure required for photoelectric conversion, such as a transport layer and an absorption layer.

The encapsulation structure 30 is disposed on the side of the cell body 20 facing away from the substrate 10, and the encapsulation structure 30 covers the cell body 20. Similar to a thin film encapsulation of a display panel, the encapsulation structure 30 may include at least a first inorganic layer 31, a first organic layer 32, and a second inorganic layer 33. The alternately disposed inorganic and organic layers can form a complete and reliable encapsulation to prevent the internal cell body 20 from coming into contact with moisture in the external environment, thereby improving the encapsulation reliability.

In one embodiment, both the first inorganic layer 31 and the second inorganic layer 33 may be formed by means of chemical vapor deposition, especially a low-temperature plasma enhanced chemical vapor deposition (PECVD) process to form a uniform and dense film layer and reduce the impact of the preparation process on the cell body 20. Main components of the two inorganic layers may include at least one of silicon nitride, silicon oxide, and silicon oxynitride. Correspondingly, the first organic layer 32 may be prepared by an inkjet printing process, and a main component of the first organic layer may include at least one of organic materials commonly used in the thin film encapsulation of a display panel, such as polyacrylate and epoxy resin.

On this basis, the use of the encapsulation structure 30 as an encapsulation of the photovoltaic cell 100 may effectively prevent the cell body 100 from intrusion of the external moisture and oxygen, and the flexibility may be achieved by the organic layer, making the photovoltaic cell 100 applicable to flexible applications.

In some embodiments, at least part of the encapsulation structure 30 is connected to the substrate 10, and the substrate 10 includes a barrier wall which surrounds an orthographic projection of the first organic layer 32 on the substrate. 10.

Similar to the thin film encapsulation of a display panel, the encapsulation structure 30 can be connected to the substrate 10 to completely enclose the cell body 20 therebetween. Meanwhile, the barrier wall structure provided on the substrate 10 limits an extension range of the first organic layer 32, and the first organic layer 32 is limited in a region enclosed by the barrier wall structure, and a side edge of the first organic layer 32 is covered by at least one of the first inorganic layer 31 and the second inorganic layer 33 by expanding coverage areas of the two inorganic layers on two sides. In this case, the entire first organic layer 32 can be covered by the contact between the inorganic layers, preventing the first organic layer 32 from interference by the external moisture and oxygen.

In order to prevent an edge of the first organic layer 32 from going beyond, a plurality of barrier walls parallel to each other may be provided on the substrate 10 to improve the blocking reliability.

In some embodiments, a light extraction suppression layer 40 is provided between the cell body 20 and the encapsulation structure 30. The light extraction suppression layer 40 includes a third inorganic layer 41. The third inorganic layer 41 has a refractive index less than or equal to 1.4.

The photovoltaic cell 100 in the embodiment of the present application may be further provided with a light extraction suppression layer 40 between the cell body 20 and the encapsulation structure 30, that is, on a side of the cell body 20 close to the back side 102. The light extraction suppression layer 40 is configured and at least part of light transmitting the cell body 20 is reflected back into the cell body 20, to suppress the light extraction at this layer structure, thereby improving the light conversion efficiency of the cell body 20.

In particular, the light extraction suppression layer 40 may include at least the third inorganic layer 41. The third inorganic layer 41 has a low refractive index, and at least part of the light emitted from a high-refractive-index layer structure towards a low-refractive-index layer structure may be totally reflected at the interface, to suppress light extraction at the interface. Meanwhile, the provision of the third inorganic layer 41 at the interface may also prevent damage to a structure in the cell body 20 during the subsequent preparation process of the encapsulation structure 30, thereby further improving the overall reliability of the photovoltaic cell 100.

In one embodiment, the third inorganic layer 41 may have the same shape and size as the cell body 20 and be disposed directly opposite to the cell body in the thickness direction X to achieve a complete function of suppressing the light extraction. Moreover, the third inorganic layer 41 may be made of at least one of inorganic substances having a refractive index less than or equal to 1.4, such as lithium fluoride and magnesium fluoride, and mixtures thereof.

In some embodiments, the first inorganic layer 31, the first organic layer 32, and the second inorganic layer 33 each have a refractive index less than or equal to 1.4.

Similar to the principle of operation of the third inorganic layer 41 described above, three layer structures in the encapsulation structure 30 stacked sequentially in an inorganic-organic-inorganic order may each have a small refractive index, to further suppress the light extraction at the encapsulation structure 30. The refractive index may be specifically less than or equal to 1.4. Since the layer structures in the encapsulation structure 30 each have a low refractive index, light that is incident to and passes through the cell body 20 can be reflected at the interface and return to the cell body 20, and the utilization of light is improved, thereby increasing the photoelectric conversion efficiency of the cell. The principle of operation is similar to that of the third inorganic layer 41 described above, which is not repeated in the present application.

In some embodiments, the light extraction suppression layer 40 further includes a second organic layer 42. The second organic layer 42 is disposed between the third inorganic layer 41 and the cell body 20, and the second organic layer 42 has a refractive index less than or equal to 1.5.

In order to further enhance the light extraction suppression function, the light extraction suppression layer 40 in the embodiments of the present application may further include a second organic layer 42. The second organic layer 42 may also be a layer structure having a low refractive index, and, stacked with the third inorganic layer 41, may further reduce the amount of light emergent from the back side 102, thereby improving the light conversion efficiency.

Similar to the third inorganic layer 41, the cell body 20, the third inorganic layer 41, and the second organic layer 42 may have the same shape and size and be disposed directly opposite to each other in the thickness direction X to achieve a desired effect of suppressing the light extraction. Moreover, the second organic layer 42 having a low refractive index may be made of at least one of organic materials having a refractive index less than or equal to 1.5, such as low-refractive-index organic silicone resin and organic fluororesin, and mixtures thereof.

In some embodiments, the cell body 20 includes a first electrode 21 disposed on a side close to the encapsulation structure 30, and the first electrode 21 has a refractive index less than or equal to 1.4.

As described above, the cell body 20 may include the perovskite functional film layer and electrode layers on two sides of the functional film layer. The electrode on the side close to the encapsulation structure 30 is a first electrode 21. Similar to the third inorganic layer 41 and the second organic layer 42 in the light extraction suppression layer 40, in addition to the function of conducting in the cell body 20, the first electrode 21 may also be made of a material having a low refractive index and stacked with the light extraction suppression layer 40, to further improve the light extraction suppression effect. The refractive index of the electrode may be adjusted by adjusting at least one of the composition, the film layer structure, and the processing process of the electrode, as long as the finally formed film layer can have a refractive index less than or equal to 1.4.

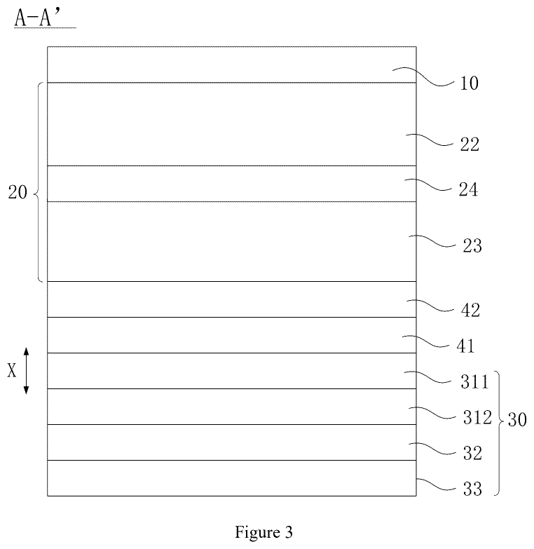

Referring to FIG. 3, FIG. 3 is another cross-sectional view taken along line A-A′ in FIG. 1. In some embodiments, the first inorganic layer 31 includes a first sublayer 311 and a second sublayer 312. The second sublayer 312 is disposed between the first sublayer 311 and the first organic layer 32, and the first sublayer 311 has a refractive index less than a refractive index of the second sublayer 312.

In the embodiments of the present application, the first inorganic layer 31 may include a stack of a plurality of layers, and may specifically include at least a first sublayer 311 and a second sublayer 312 which are stacked. The first sublayer 311 may have a lower refractive index. Similar to the light extraction suppression layer 40 and the first electrode 21 described above, a film layer structure having a low refractive index may further reduce the amount of light emergent from the back side 102.

In one embodiment, the first sublayer 311 may also be a film layer structure having a refractive index less than or equal to 1.4, and the first sublayer 311 and the second sublayer 312 may be made of the same material. During the preparation process, by adjusting the ratio of silicon nitride to silicon oxide, a density of the film layer structure, or other parameters, the refractive index of the film layer structure can be adjusted to be less than or equal to 1.4 while being less than the refractive index of the second sublayer 312, to provide a good effect of light extraction suppression.

In one embodiment, the first sublayer 311 and the second sublayer 312 may each have the same shape as the cell body 20 and have a size greater than a size of the cell body 20, to achieve a function required for encapsulation while suppressing the light extraction.

In some embodiments, the cell body 20 includes a first sub-body 22 and a second sub-body 23, a light extraction promotion layer 24 is provided between the first sub-body 22 and the second sub-body 23 which are electrically connected to each other by the light extraction promotion layer 24, and at least part of the light extraction promotion layer 24 has a refractive index greater than or equal to 1.7.

In the embodiments of the present application, the cell body 20 may include a first sub-body 22 and a second sub-body 23. The first sub-body 22 may be a perovskite photovoltaic cell, and the second sub-body 23 may be a photovoltaic cell that is disposed on a side of the first sub-body 22 close to the back side 102 and that receives light passing through the first sub-body 22. A light conversion material of the second sub-body 23 may be the same as or different from that of the first sub-body 22, that is, the second sub-body 23 may be a perovskite photovoltaic cell, a crystalline silicon cell, a conventional thin film photovoltaic cell, etc., as long as it can receive the light that the first sub-body 22 fails to completely convert.

In this case, the first sub-body 22 and the second sub-body 23 are still in the same cell structure, and electrodes on their sides close to each other may be directly and electrically connected by a conductive film layer. In this case, electrode connecting terminals may be respectively led out from an electrode on a side of the first sub-body 22 close to the substrate 10 and an electrode on a side of the second sub-body 23 close to the encapsulation structure 30, that is, a two-terminal stacked photovoltaic cell structure may be formed, thereby improving the overall light conversion efficiency.

On this basis, a light extraction promotion layer 24 may be provided between the second sub-body 23 and the first sub-body 22. Such a layer structure has a high refractive index to facilitate emission of light passing through the first sub-body 22, and the light that is not absorbed by the first sub-body 22 can be extracted outside the first sub-body 22 more effectively, thereby improving the photoelectric conversion efficiency of the underlying second sub-body 23 and thus the overall performance of the photovoltaic cell 100. In one embodiment, the light extraction promotion structure 24 should have a refractive index greater than or equal to 1.7 to ensure the effect of light extraction promotion.

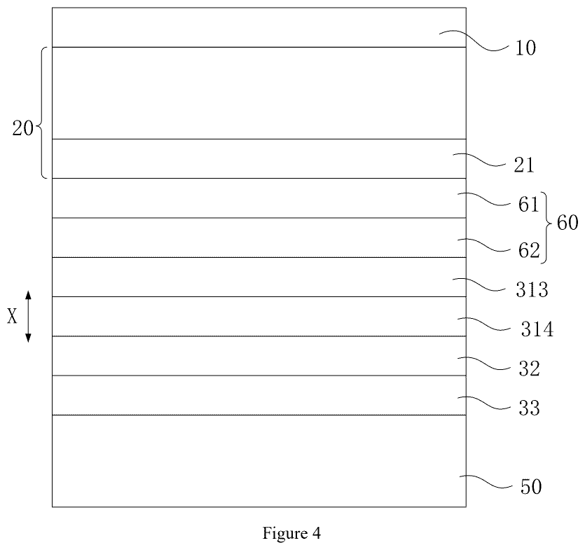

Referring to FIG. 4, FIG. 4 is yet another cross-sectional view taken along line A-A′ in FIG. 1. The embodiments of the present application provide a photovoltaic cell module 200, including a substrate 10, a cell body 20, an encapsulation structure 30, and a bottom supplementary cell 50. The cell body 20 is disposed on a surface of a side of the substrate 10 close to a light-facing side 101. The encapsulation structure 30 is disposed on a side of the cell body 20 facing away from the substrate 10, an orthographic projection of the encapsulation structure 30 covers an orthographic projection of the cell body 20 in a thickness direction X, and the encapsulation structure 30 includes a first inorganic layer 31, a first organic layer 32 and a second inorganic layer 33 which are stacked sequentially in a direction away from the cell body 20. The bottom supplementary cell 50 is disposed on a side of the encapsulation structure 30 facing away from the cell body 20 and stacked with the encapsulation structure 30. A light extraction module 60 is provided between the cell body 20 and the encapsulation structure 30.

The present application provides a photovoltaic cell module 200. On the basis of the embodiment in the embodiments in which the photovoltaic cell 100 is provided with a first sub-body 22 and a second sub-body 23, in the photovoltaic cell module 200 the bottom cell for receiving the light that the overlaying perovskite photovoltaic cell fails to convert may be disposed outside the encapsulation structure 30, that is, the bottom cell and the overlaying cell body 20 may be disposed independently of each other. In this case, electrode connecting terminals may be respectively led out from electrodes on two sides of the cell body 20 and the bottom supplementary cell 50 to form a four-terminal stacked structure.

On this basis, a light extraction module 60 may also be provided between the cell body 20 and the encapsulation structure 30 and configured and the unconverted light is extracted from the cell body 20 and then transmit to the bottom supplementary cell 50 for photoelectric conversion again, thereby improving the overall performance of the photovoltaic cell module 200. The specific configuration manner of the light extraction module is similar to that of the light extraction promotion layer described above, which is not repeated in the present application.

In some embodiments, the cell body 20 includes a first electrode 21 disposed on a side close to the encapsulation structure 30, and the first electrode 21 has a refractive index less than or equal to 1.4. The light extraction module 60 includes an extraction layer 61 and a fourth inorganic layer 62 which are stacked sequentially in a direction from the cell body 20 to the encapsulation structure 30. The extraction layer 61 has a refractive index greater than or equal to 1.7, and the fourth inorganic layer 62 has a refractive index less than or equal to 1.4.

In the embodiment in which a light extraction module 60 is provided, the light extraction module 60 may include a plurality of film layer structures which are stacked. In one embodiment, the light extraction module includes at least the extraction layer 61 and the fourth inorganic layer 62. The extraction layer 61 may be made of the same material as an optical extraction layer in a display panel for increasing the brightness of emergent light, both materials having a high refractive index and achieving a similar effect. Similar to the inorganic layer in the light extraction suppression layer 40 described above, the fourth inorganic layer 62 may have a low refractive index.

Further, in the cell body 20, an electrode on the side close to the encapsulation structure 30 may be the first electrode 21 having a low refractive index, and in this case the low-refractive-index first electrode 21, the high-refractive-index extraction layer 61 and the low-refractive-index fourth inorganic layer 62 which are stacked sequentially in the thickness direction X are formed in the photovoltaic cell 100, to form a film layer structure with low-high-low refractive indexes, and light incident to the three film layers may be more easily reflected at interfaces therebetween when transferring between the three film layers, forming a Fabry-Pérot (F-P) microcavity structure to further improve the light extraction efficiency and transmit more unconverted light to the underlying bottom supplementary cell 50, thereby improving the overall performance of the photovoltaic cell 100.

In one embodiment, the fourth inorganic layer 62 can prevent damage to the extraction layer 61, which is typically made of an organic material, in a subsequent process step for preparing the first inorganic layer 31, thereby improving the overall reliability of the photovoltaic cell 100.

In some embodiments, the extraction layer 61 has a thickness ranging from 50 nm to 100 nm, and the fourth inorganic layer 62 has a thickness ranging from 20 nm to 80 nm.

As described above, the F-P microcavity structure may be formed between the layer structures that are stacked sequentially and that have varied low-high-low refractive indexes, thereby improving a light extraction rate via a microcavity. On this basis, by adjusting the thickness of each layer structure, that is, the length of the F-P microcavity, reflection and interference effects of light in the microcavity may be adjusted accordingly. When the length of the microcavity reaches a specific value, the transmittance of light of a specific wavelength may be increased accordingly via light resonance.

In one embodiment, when the length of the microcavity is denoted as L, a half wavelength of light to be subjected to transmission enhancement is denoted as λ, and the magnitude of an included angle between the incident light and a normal is denoted as θ, L is directly proportional to λ and inversely proportional to cos θ according to a principle of interference of light in the F-P microcavity. In one embodiment, the length of the microcavity may be adjusted to adjust the transmittance of light of different wavelengths through the microcavity, to allow transmission of light of a specific wavelength that the bottom supplementary cell 50 has an absorption advantage. On this basis, the extraction layer 61 may have a thickness ranging from 50 nm to 100 nm, and the fourth inorganic layer 62 may have a thickness ranging from 20 nm to 80 nm. The specific values may be designed according to parameters such as processing conditions, incident light parameters, and the specific material of a photoelectric conversion structure in the bottom supplementary cell 50, and any appropriate values may be selected.

In some embodiments, the first inorganic layer 31 includes a third sublayer 313 and a fourth sublayer 314 which are stacked sequentially in the direction away from the cell body 20, the third sublayer 313 having a refractive index greater than or equal to 1.7, and the fourth sublayer 314 having a refractive index less than or equal to 1.4.

On the basis of the extraction layer 61 and the fourth inorganic layer 61 described above, the first inorganic layer 31 may include a third sublayer 313 and a fourth sublayer 314 which are disposed sequentially, the third sublayer 313 having a higher refractive index, and the fourth sublayer 314 maintaining a lower refractive index.

On this basis, the photovoltaic cell 100 includes a low-refractive-index first electrode 21, a high-refractive-index first extraction layer 61, a low-refractive-index fourth inorganic layer 62, a high-refractive-index third sublayer 313, and a low-refractive-index fourth sublayer 314 which are disposed sequentially and in succession, to form two film layer microcavity structures that are disposed sequentially and that have low-high-low refractive indexes, that is, F-P microcavity structures that are formed in the thickness direction X and that share the low-refractive-index fourth inorganic layer 62, thereby further improving the light extraction efficiency and thus the overall performance of the photovoltaic cell 100. The specific principle is the same as that of the microcavity structure described above, which is not repeated in the present application.

In some embodiments, the third sublayer 313 has a thickness ranging from 700 nm to 1200 nm, and the fourth sublayer 314 has a thickness ranging from 5 nm to 20 nm.

Similar to the thickness settings of the extraction layer 61 and the fourth inorganic layer 61 described above, in order to enable the F-P microcavity formed by the fourth inorganic layer 62, the third sublayer 313, and the first sublayer 314 to achieve the same effect of increasing the transmittance of light of a specific wavelength, the thickness of each layer structure may be adjusted to accordingly adjust the length of the formed microcavity. Further, the third sublayer 313 may have a thickness ranging from 700 nm to 1200 nm, and the fourth sublayer 314 may have a thickness ranging from 5 nm to 20 nm. In the design of the thicknesses of the layer structures, the two F-P microcavities formed by the first electrode 21, the extraction layer 61, the fourth inorganic layer 62, the third sublayer 313, and the fourth sublayer 314 may achieve a high transmittance effect for the light in the same wavelength range to further increase the amount of light that can be received by the bottom supplementary cell 50, thereby improving the photoelectric conversion efficiency.

In some embodiments, a long-wavelength pass filter is also provided between the encapsulation structure 30 and the bottom supplementary cell 50.

In order to further increase the amount of incident light of a specific wavelength that can be received by the bottom supplementary cell 50, the long-wavelength pass filter may also be provided between the encapsulation structure 30 and the bottom supplementary cell 50. An orthographic projection of the filter in the thickness direction X can cover the bottom supplementary cell 50, and the filter has the same thickness at various portions, to achieve a uniform increase of the transmittance in each portion. In one embodiment, the long-wavelength pass filter may have the same shape as and be disposed concentrically with the bottom supplementary cell 50.

The long-wavelength pass filter refers to a type of filter that has high transmittance for light in a long-wavelength direction and that cuts off light in a short-wavelength direction. By providing the long-wavelength pass filter between the encapsulation structure 30 and the bottom supplementary cell 50, light of a long wavelength may be incident to the bottom supplementary cell 50 at a small loss, and interference by short-wave light that is not easy to receive and convert may also be avoided. Accordingly, the cell body 20 may be configured to have a strong absorption capacity for short-wave light, and the bottom supplementary cell 50 may be configured to have a strong absorption capacity for long-wave light, and they cooperate with each other to further improve the overall photoelectric conversion efficiency of the photovoltaic cell module 200.

In some embodiments, the cell body 20 is a perovskite photovoltaic cell, the bottom supplementary cell 50 is a crystalline silicon cell, and the long-wavelength pass filter has a cut-on wavelength ranging from 600 nm to 800 nm.

In the embodiment in which the long-wavelength pass filter is provided, the cell body 20 may perform good absorption for short-wave light, and the bottom supplementary cell 50 may perform good absorption for long-wave light. In one embodiment, the cell body 20 and the bottom supplementary cell 50 may be respectively made of different photoelectric conversion materials to adjust their wavelength ranges that can be strongly received. On this basis, the cell body 20 may be configured as a perovskite photovoltaic cell, which has a good absorption effect on short-wave light having a wavelength ranging from 400 nm to 800 nm. Correspondingly, the bottom supplementary cell 50 may be configured as a crystalline silicon cell, which has a good absorption effect on long-wave light having a wavelength ranging from 600 nm to 900 nm, thereby being able to fully use the light incident to the photovoltaic cell module 200.

Further, in view of the absorption of light of different wavelengths by the two photoelectric conversion materials described above, the cut-on wavelength of the long-wavelength pass filter may be adjusted accordingly. The long-wavelength pass filter has high transmittance for long-wave light having a wavelength greater than the cut-on wavelength, and has a cut-off effect on short-wave light having a wavelength less than the cut-on wavelength. Thus, the long-wavelength pass filter may have a cut-on wavelength ranging from 600 nm to 800 nm to correspond to the two materials described above, thereby improving the overall photoelectric conversion efficiency of the photovoltaic cell module 200.

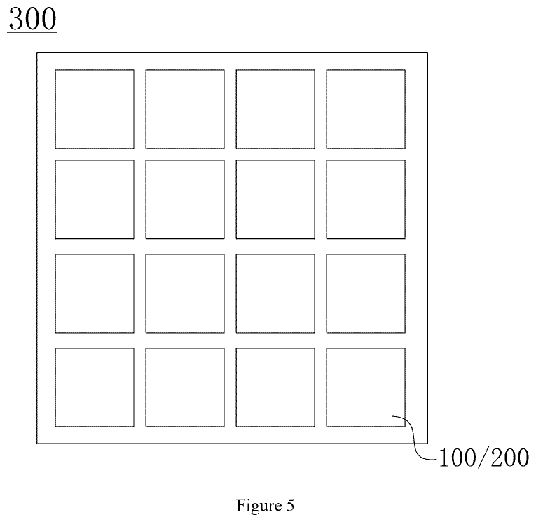

Referring to FIG. 5, FIG. 5 is a structural schematic diagram of a photovoltaic cell assembly according to an embodiment of the present application. In one embodiment, the embodiments of the present application provide a photovoltaic cell assembly 300, including a photovoltaic cell 100 according to any one of the embodiments or a photovoltaic cell module 200 according to any one of the embodiments.

The embodiments of the present application further provide a photovoltaic cell assembly 300, which may include at least one photovoltaic cell 100 or at least one photovoltaic cell module 200, and corresponding accessories such as traces and busbars for connecting the photovoltaic cell 100. In the embodiment in which each photovoltaic cell assembly 300 is provided with a plurality of photovoltaic cells 100 or a plurality of photovoltaic cell modules 200, the photovoltaic cells 100/photovoltaic cell modules 200 may be connected in series, in parallel, or in a parallel-series manner, which may be designed according to the usage requirements. The photovoltaic cell assembly 300 according to the embodiments of the present application has all the beneficial effects of the photovoltaic cell 100/photovoltaic cell module 200 according to the embodiments of the present application, and reference may be made to the detailed description of the photovoltaic cell 100 and the photovoltaic cell module 200 in the above embodiments, which is not repeated in this embodiment.

What is claimed is:

1. A photovoltaic cell comprising a light-facing side and a back side disposed oppositely in a thickness direction of the photovoltaic cell, the photovoltaic cell comprising:
a substrate;
at least a cell body disposed on a surface of one side of the substrate; and
an encapsulation structure disposed on a side of the cell body facing away from the substrate, wherein an orthographic projection of the encapsulation structure covers an orthographic projection of the cell body in the thickness direction, and the encapsulation structure comprises a first inorganic layer, a first organic layer and a second inorganic layer which are stacked sequentially in a direction away from the cell body.

2. The photovoltaic cell according to claim 1, wherein at least part of the encapsulation structure is connected to the substrate, and the substrate comprises at least a barrier wall which surrounds an orthographic projection of the first organic layer on the substrate.

3. The photovoltaic cell according to claim 1, wherein a light extraction suppression layer is provided between the cell body and the encapsulation structure, and the light extraction suppression comprises a third inorganic layer having a refractive index less than or equal to 1.4.

4. The photovoltaic cell according to claim 3, wherein the light extraction suppression layer further comprises a second organic layer disposed between the third inorganic layer and the cell body, and the second organic layer has a refractive index less than or equal to 1.5.

5. The photovoltaic cell according to claim 3, wherein each of the first inorganic layer, the first organic layer and the second inorganic layer has a refractive index less than or equal to 1.4.

6. The photovoltaic cell according to claim 3, wherein the cell body comprises a first electrode disposed on a side close to the encapsulation structure, and the first electrode has a refractive index less than or equal to 1.4.

7. The photovoltaic cell according to claim 3, wherein the first inorganic layer comprises a first sublayer and a second sublayer, the second sublayer being disposed between the first sublayer and the first organic layer, and the first sublayer having a refractive index less than a refractive index of the second sublayer.

8. The photovoltaic cell according to claim 3, wherein the cell body comprises a first sub-body and a second sub-body, a light extraction promotion layer is provided between the first sub-body and the second sub-body, the first sub-body is electrically connected to the second sub-body by the light extraction promotion layer, and at least part of the light extraction promotion layer has a refractive index greater than or equal to 1.7.

9. The photovoltaic cell according to claim 8, wherein the light extraction promotion layer has a thickness ranging from 50 nm to 100 nm.

10. The photovoltaic cell according to claim 8, wherein the second sub-body is disposed on a side of the first sub-body close to the back side to receive light passing through the first sub-body.

11. The photovoltaic cell according to claim 8, wherein the first sub-body is a perovskite photovoltaic cell; and the second sub-body is a perovskite photovoltaic cell, a crystalline silicon cell, or a conventional thin film photovoltaic cell.

12. A photovoltaic cell module, comprising:
a substrate;
at least a cell body disposed on a surface of one side of the substrate;
an encapsulation structure disposed on a side of the cell body facing away from the substrate, an orthographic projection of the encapsulation structure covering an orthographic projection of the cell body in a thickness direction, and the encapsulation structure comprising a first inorganic layer, a first organic layer and a second inorganic layer which are stacked sequentially in a direction away from the cell body; and
a bottom supplementary cell disposed on a side of the encapsulation structure facing away from the cell body and stacked with the encapsulation structure, wherein a light extraction module is provided between the cell body and the encapsulation structure.

13. The photovoltaic cell module according to claim 12, wherein at least part of the encapsulation structure is connected to the substrate, and the substrate comprises at least a barrier wall which surrounds an orthographic projection of the first organic layer on the substrate.

14. The photovoltaic cell module according to claim 12, wherein the cell body comprises a first electrode disposed on a side close to the encapsulation structure, the first electrode having a refractive index less than or equal to 1.4; and
the light extraction module comprises an extraction layer and a fourth inorganic layer which are stacked sequentially in a direction from the cell body to the encapsulation structure, the extraction layer having a refractive index greater than or equal to 1.7, and the fourth inorganic layer having a refractive index less than or equal to 1.4.

15. The photovoltaic cell module according to claim 14, wherein the extraction layer has a thickness ranging from 50 nm to 100 nm, and the fourth inorganic layer has a thickness ranging from 20 nm to 80 nm.

16. The photovoltaic cell module according to claim 12, wherein the first inorganic layer comprises a third sublayer and a fourth sublayer which are stacked sequentially in the direction away from the cell body, the third sublayer having a refractive index greater than or equal to 1.7, and the fourth sublayer having a refractive index less than or equal to 1.4.

17. The photovoltaic cell module according to claim 16, wherein the third sublayer has a thickness ranging from 700 nm to 1200 nm, and the fourth sublayer has a thickness ranging from 5 nm to 20 nm.

18. The photovoltaic cell module according to claim 12, wherein a long-wavelength pass filter is further provided between the encapsulation structure and the bottom supplementary cell.

19. The photovoltaic cell module according to claim 18, wherein the cell body is a perovskite photovoltaic cell, the bottom supplementary cell is a crystalline silicon cell, and the long-wavelength pass filter has a cut-on wavelength ranging from 600 nm to 800 nm.

20. A photovoltaic cell assembly, comprising:
a photovoltaic cell, comprising a light-facing side and a back side disposed oppositely in a thickness direction of the photovoltaic cell, the photovoltaic cell comprising:
a substrate;
at least a cell body disposed on a surface of one side of the substrate; and
an encapsulation structure disposed on a side of the cell body facing away from the substrate, wherein an orthographic projection of the encapsulation structure covers an orthographic projection of the cell body in the thickness direction, and the encapsulation structure comprises a first inorganic layer, a first organic layer and a second inorganic layer which are stacked sequentially in a direction away from the cell body.
